(19) United States
(12) Patent Application Publication
(10) Pub. No.: US 2022/0114293 A1
(43) Pub. Date: Apr. 14, 2022

(54) METHODS, SYSTEMS, AND MEDIA FOR GENERATIVE URBAN DESIGN WITH USER-GUIDED OPTIMIZATION FEATURES

(71) Applicant: Sidewalk Labs LLC, New York, NY (US)

(72) Inventors: Tess Bianchi, New York, NY (US); Roshan Agrawal, New York, NY (US); Saif Haobsh, New York, NY (US)

(21) Appl. No.: 17/497,541

(22) Filed: Oct. 8, 2021

Related U.S. Application Data
(60) Provisional application No. 63/089,692, filed on Oct. 9, 2020.

(51) Int. Cl. G06F 30/13; G06F 30/20

(52) U.S. Cl. CPC G06F 30/13; G06F 30/20

(57) ABSTRACT

Methods, systems, and media for generative urban design with user-guided optimization features are provided. In some embodiments, the method comprises: generating a first plurality of district designs using a genetic algorithm of a generative design system; causing the first plurality of district designs to be presented in a grid representation for evaluation by a user of a computing device, wherein each region of the grid representation is associated with one of the first plurality of district designs and wherein each region of the grid representation is selectable by the user of the computing device; receiving, from the user of the computing device, a selected region corresponding to a district design from the first plurality of district designs being presented in the grid representation; and, in response to receiving the selected region, inputting the selected district design as a seed to the genetic algorithm of the generative design system to generate a second plurality of district designs and replacing the first plurality of district designs in the grid representation with the second plurality of district designs for evaluation by the user of the computing device.

### CROSS-REFERENCE TO RELATED APPLICATIONS

This application claims the benefit of U.S. Provisional Patent Application No. 63/089,692, filed Oct. 9, 2020, which is hereby incorporated by reference herein in its entirety.

### TECHNICAL FIELD

The disclosed subject matter relates to methods, systems, and media for generative urban design with user-guided optimization features.

### BACKGROUND

Development teams can be highly unique in their desires and/or preferences. For example, a development team or developer may hone their competitive advantage by specializing in specific building types with particular geometric characteristics. In another example, a development team or developer may hone their competitive advantage by specializing in specific building types that are optimized for unique priority outcomes—e.g., some developers may specialize in vertical mixed use development in which commercial and/or retail spaces are configured on lower floors of buildings while residential units are reserved for higher floors of buildings in order to improve walkability between housing, workplaces, and other amenities, while other developers may specialize in horizontal mixed use development in which some single-use buildings are reserved for residential units and other single-use buildings are reserved for commercial and/or retail spaces also in order to improve walkability between housing, workplaces, and other amenities. Each approach has its benefits and drawbacks, but a developer may be inclined to stick with the same approach. This also typically requires many subcontractors to create these models. Additionally, as a development team hones their approach, the models that they build can begin to lack variety.

Thus, it is useful to automatically generate additional recommended designs that reflect the desires of the development team and create additional options and/or a variety of different options based on those preferences.

Accordingly, it is desirable to provide new methods, systems, and media for generative urban design with user-guided optimization features.

### SUMMARY

Methods, systems, and media for generative urban design with user-guided optimization features are provided.

In accordance with some embodiments of the disclosed subject matter, a method for evaluating design variants of proposed districts is provided, the method comprising: generating, by a hardware processor, a first plurality of district designs using a genetic algorithm of a generative design system; causing, by the hardware processor, the first plurality of district designs to be presented in a grid representation for evaluation by a user of a computing device, wherein each region of the grid representation is associated with one of the first plurality of district designs and wherein each region of the grid representation is selectable by the user of the computing device; receiving, from the user of the computing device, a selected region corresponding to a district design from the first plurality of district designs being presented in the grid representation; and, in response to receiving the selected region, inputting, by the hardware processor, the selected district design as a seed to the genetic algorithm of the generative design system to generate a second plurality of district designs and replacing the first plurality of district designs in the grid representation with the second plurality of district designs for evaluation by the user of the computing device.

In some embodiments, the method further comprises: determining a score for each district design in the first plurality of district designs; selecting a first subset of the first plurality of district designs based on the determined score; and mutating, using the genetic algorithm of the generative design system, the first subset of the first plurality of district designs to generate a second subset of the first plurality of district designs, wherein the first subset of the first plurality of district designs are presented in the grid representation. In some embodiments, the score is based on open space percentage, daylight percentage, and total gross floor area of a district design.

In some embodiments, in response to receiving the selected region corresponding to the district design from the first plurality of district designs being presented in the grid representation, a user interface that includes an enlarged view of the design district is presented, wherein a plurality of views of the design district are available. In some embodiments, the enlarged view of the design district highlights a portion of the district design that was modified by the genetic algorithm of the generative design system in comparison with the selected district design.

In some embodiments, a plurality of selected regions corresponding to a subset of the district designs is received and, in response to receiving the plurality of selected regions, the subset of district designs is input as seeds to the genetic algorithm of the generative design system to generate the second plurality of district designs and the first plurality of district designs in the grid representation is replaced with the second plurality of district designs for evaluation by the user of the computing device.

In some embodiments, in response to receiving the selected region corresponding to the district design from the first plurality of district designs being presented in the grid representation, a thumbnail representation of the selected district design is presented in a window region that is adjacent to the grid representation.

In some embodiments, in response to receiving the selected region corresponding to the district design from the first plurality of district designs being presented in the grid representation, the selected district design is positioned in a central region of the grid representation. In some embodiments, the grid representation is associated with axes that each correspond to a parameter and each of the second plurality of district designs is positioned within the grid representation based on a parameter value of one of the second plurality of district designs in relation to the parameter value of the selected district design in the central region of the grid representation. In some embodiments, the parameter associated with each axis is selectable by the user of the computing device.

In accordance with some embodiments of the disclosed subject matter, a system for evaluating design variants of proposed districts is provided, the system comprising a hardware processor that is configured to: generate a first plurality of district designs using a genetic algorithm of a generative design system; cause the first plurality of district designs to be presented in a grid representation for evaluation by a user of a computing device, wherein each region of the grid representation is associated with one of the first plurality of district designs and wherein each region of the grid representation is selectable by the user of the computing device; receive, from the user of the computing device, a selected region corresponding to a district design from the first plurality of district designs being presented in the grid representation; and, in response to receiving the selected region, input the selected district design as a seed to the genetic algorithm of the generative design system to generate a second plurality of district designs and replacing the first plurality of district designs in the grid representation with the second plurality of district designs for evaluation by the user of the computing device.

In accordance with some embodiments of the disclosed subject matter, a non-transitory computer-readable medium containing computer executable instructions that, when executed by a processor, cause the processor to perform a method for evaluating design variants of proposed districts is provided, the method comprising: generating a first plurality of district designs using a genetic algorithm of a generative design system; causing the first plurality of district designs to be presented in a grid representation for evaluation by a user of a computing device, wherein each region of the grid representation is associated with one of the first plurality of district designs and wherein each region of the grid representation is selectable by the user of the computing device; receiving, from the user of the computing device, a selected region corresponding to a district design from the first plurality of district designs being presented in the grid representation; and, in response to receiving the selected region, inputting the selected district design as a seed to the genetic algorithm of the generative design system to generate a second plurality of district designs and replacing the first plurality of district designs in the grid representation with the second plurality of district designs for evaluation by the user of the computing device.

In accordance with some embodiments of the disclosed subject matter, a system for evaluating design variants of proposed districts is provided, the system comprising: means for generating a first plurality of district designs using a genetic algorithm of a generative design system; means for causing the first plurality of district designs to be presented in a grid representation for evaluation by a user of a computing device, wherein each region of the grid representation is associated with one of the first plurality of district designs and wherein each region of the grid representation is selectable by the user of the computing device; means for receiving, from the user of the computing device, a selected region corresponding to a district design from the first plurality of district designs being presented in the grid representation; and means for inputting the selected district design as a seed to the genetic algorithm of the generative design system to generate a second plurality of district designs and means for replacing the first plurality of district designs in the grid representation with the second plurality of district designs for evaluation by the user of the computing device in response to receiving the selected region.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an illustrative example of a user interface for receiving a first user-selected design variant and generating similar design variants based on the first user-selected design variant in accordance with some embodiments of the disclosed subject matter.

FIG. 2 shows an illustrative example of a user interface for receiving a subsequent user-selected design option from the and similar district designs and generating similar district designs based on the subsequent user-selected design option in accordance with some embodiments of the disclosed subject matter.

FIG. 3 shows an illustrative example of a user interface including multiple district designs in accordance with some embodiments of the disclosed subject matter.

FIG. 4 shows an illustrative example of a user interface for generating similar design variants based on a user-selected design variant that is placed in a central portion of the user interface in accordance with some embodiments of the disclosed subject matter.

FIG. 5 shows an illustrative example of an alternative user interface for generating similar design variants in which multiple user-selected design variants are received in accordance with some embodiments of the disclosed subject matter.

FIG. 6 shows a schematic diagram of an illustrative system suitable for implementation of mechanisms described herein for generative urban design with user-guided optimization features in accordance with some embodiments of the disclosed subject matter.

FIG. 7 shows a detailed example of hardware that can be used in a server and/or a user device of FIG. 6 in accordance with some embodiments of the disclosed subject matter.

### DETAILED DESCRIPTION

In accordance with various embodiments, mechanisms (which can include methods, systems, and media) for generative urban design with user-guided optimization features are provided.

In many generative design systems, genetic algorithms, such as nondominated sorting genetic algorithms, can be used to optimize or otherwise improve the performance of districts and other designs. For example, genetic algorithms can be used to generate a batch of districts from a random seed of input data, select the top scoring districts in that batch according to some set of criteria (e.g., the designs having the best possible features for reproducing in future districts), and slightly modify or mutate the districts to create a set of possible design solutions for the district. That is, in genetic algorithms for generating districts or other designs, the fittest solutions from a population of possible solutions can be selected for reproduction, where their genes or parameters are passed on to generate future districts or future designs.

In some embodiments, the mechanisms described herein can be used to continuously generate designs (sometimes referred to herein as “variants”) based on user feedback in which one or more user-selected designs can be used by the genetic algorithm to generate a new batch or set of variants by mutating the one or more user-selected designs. For example, the genetic algorithm can be used to mutate or otherwise make modifications to the user-selected variant to generate a new batch or set of variants or design alternatives for evaluation by the user. In another example, rather than simply repeating this process with the genetic algorithm over and over, the genetic algorithm can use the user-selected variant as an input to generate a new batch of variants and can continue to generate new batches of variants by continuing to receive user input as to preferred variants from each generated batch of variants.

This can, for example, prioritize the discovery of new designs that more closely match the preferences of a user using a generative design system by generating batches of variants that match the characteristics of preferred variants that were selected by the user.

It should be noted that, although the embodiments described herein may describe the use of a generative design system to generate districts or district plans, this is merely illustrative and the user-guided optimization features described herein can be used to generate any suitable design (e.g., a building floorplan, a building configuration, an apartment mix on one or more floors, a street grid, etc.).

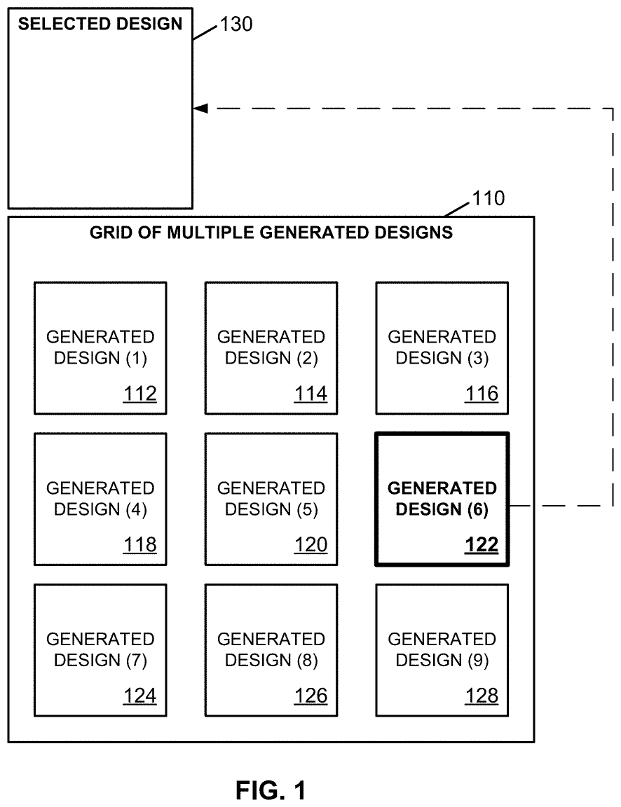

These and other features for generative urban design with user-guided optimization features are described in connection with FIGS. 1-5.

Turning to FIG. 1, the generative design system can begin by generating an initial set of variants and can select the top scoring variants from the initial set of variants based on any suitable criteria. For example, after generating an initial set of district designs, the generative design system can select the top scoring district designs based on open space percentage, daylight percentage, and total gross floor area. In continuing this example, the genetic algorithm of the generative design system may, in some instances, mutate the top scoring district designs to generate a new batch of district designs for evaluation by a user of the generative design system.

For example, as shown in FIG. 1, the generative design system can present a grid 110 that provides any suitable number of the new batch of variants for evaluation by the user of the generative design system. In a more particular example, as shown in FIG. 1, nine district designs 112-128 from the new batch of district designs can be presented within grid 110 for evaluation and/or selection by the user.

Although FIG. 1 shows that nine variants have been provided for evaluation by the user of the generative design system, this is merely illustrative and any suitable number of variants can be provided for evaluation by the user of the generative design system (e.g., ten variants, twenty variants, one hundred variants, etc.).

It should also be noted that, although FIG. 1 shows that the nine variants are presented in a 3×3 grid, this is merely illustrative and the generated variants can be presented to the user in any suitable manner. For example, the generative design system can provide a linear flipbook of the multiple variants for evaluation and/or selection by the user.

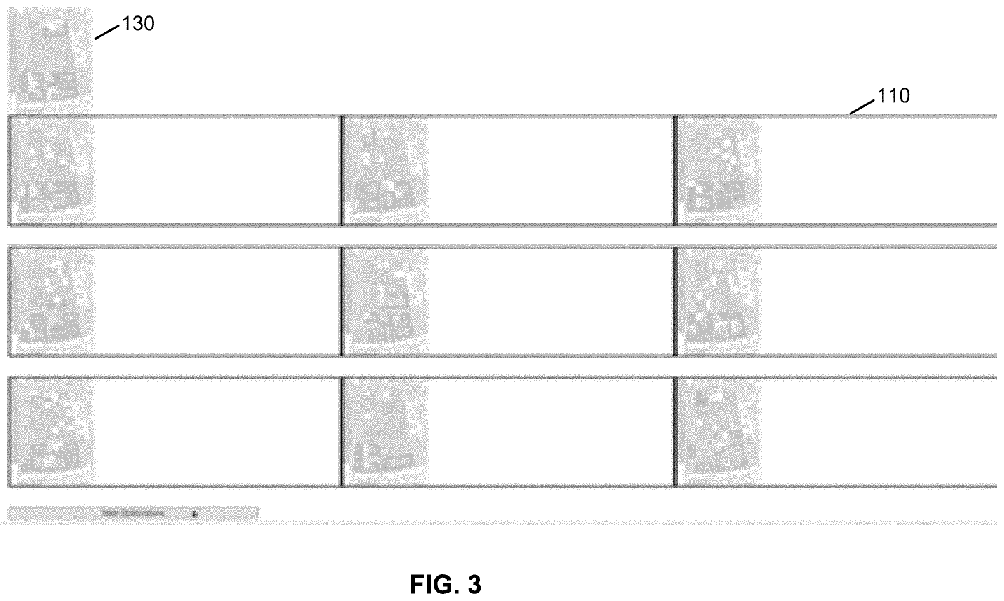

Turning back to FIG. 1, each district design 112-128 can present the user with a representation of the district design (e.g., a thumbnail representation). For example, as shown in FIG. 3, a representation of each district design 112-128 can be presented in grid 110. The user of the generative design system can interact with each representation of the district design. For example, in response to selecting a particular district design (e.g., district design 122 as illustrated by the highlight region), an enlarged view of the selected district design can be presented in which the user can manipulate the enlarged view to view different perspectives of the proposed district. In continuing this example, the enlarged view of the district design can be further selected or expanded such that a user can view details of a building within the district design.

Upon evaluating district designs 112-128, the generative design system can receive a selected variant from the user. For example, as shown in FIG. 1, the user has selected variant 122 from the multiple variants presented in grid 110. In continuing this example, the user-selected variant can be presented in region 130. For example, as shown in FIGS. 1-3, user-selected variant 122 can be presented in region 130.

It should be noted that, in some embodiments, multiple variants can be selected by the user. For example, as shown in FIG. 1, the user can evaluate each district design 112-128 and can select multiple district designs that appeal to the user. In continuing this example, the multiple user-selected district designs can be presented in region 130.

In some embodiments, the genetic algorithm of the generative design system can use the selected variant or variants as seeds to generate a next set of variants. For example, in response to receiving the selected variant or variants, the genetic algorithm of the generative design system can mutate or otherwise make modifications to the user-selected variant to generate a new batch or set of variants or design alternatives for evaluation by the user. In another example, the genetic algorithm can use the user-selected variant as an input to generate a new batch of variants and can continue to generate new batches of variants by continuing to receive user input as to preferred variants from each generated batch of variants.

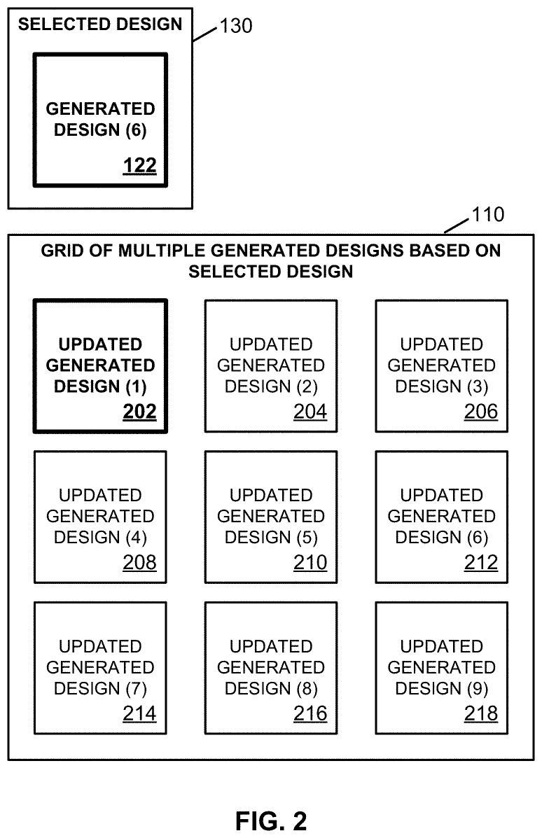

For example, as shown in FIG. 2, the user-selected variant 122 is shown in 130 and the genetic algorithm of the generative design system can re-populate grid 110 with variants that have been mutated based on the user-selected variant 122. In a more particular example, as shown in FIG. 2, nine newly generated district designs 202-218 from the new batch of district designs can be presented within grid 110 for further evaluation and/or selection by the user.

The generative design system can continue to receive user feedback while continuing to generate new variants. It should be noted that, in some embodiments, the generative design system can allow the user to select variants from different iterations of the genetic algorithm.

Accordingly, the generative design system can allow the user to continue to generate, evaluate, and select preferred designs. This can, for example, prioritize the discovery of new designs that more closely match the preferences of a user using a generative design system by generating batches of variants that match the characteristics of preferred variants that were selected by the user.

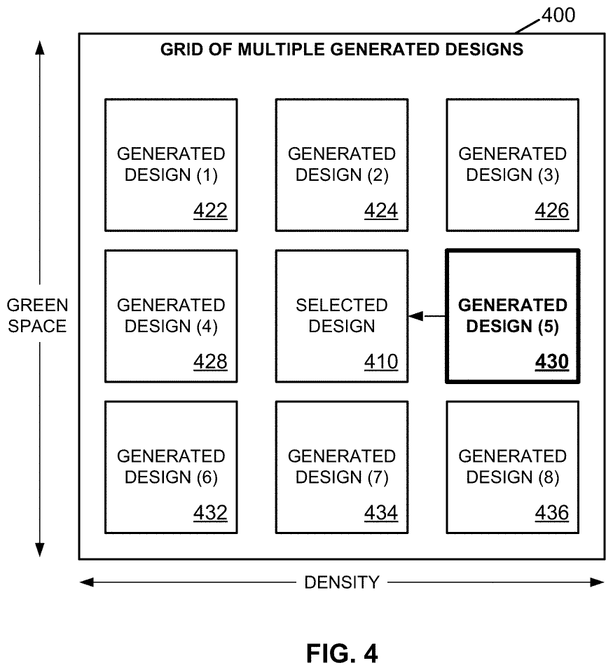

It should be noted that, although the user-selected variant is shown in 130 in FIGS. 1-3, this is merely illustrative and the user-selected variant can be presented in grid 110 in any suitable position. For example, as shown in FIG. 4, upon selecting design variant 430 (which corresponds to “generated design (5)”) in grid 400, design variant 430 can be saved for future reference by placing the selected design variant in the center of grid 400 and can be used as a seed to generate a next set of design variants. In a more particular example, in response to receiving the selected variant 430, selected design variant 430 can shift in position to region 410 at the center of grid 400 and the genetic algorithm of the generative design system can mutate or otherwise make modifications to design variant 430 to generate a new batch or set of variants or design alternatives for evaluation by the user, where the new batch of variants or design alternatives can be presented in regions 420-436 that surround the periphery of region 410 at the center of grid 400.

In some embodiments, grid 400 can include axes that correspond to particular parameters. Such parameters can be user-selected based on preferences by the user. For example, as shown in FIG. 4, the parameters can include an amount of green space on the y-axis and density on the x-axis. In a more particular example, the position of the variant or design alternative within grid 400 can provide the user with an indication as to how the user-selected variant in region 410 was mutated—e.g., a design variant positioned in region 422 may have a lower density than user-selected variant in region 410 and a greater amount of open space or green space than user-selected variant in region 410; a design variant positioned in region 424 may generally have the same density as user-selected variant in region 410 and a greater amount of open space or green space than user-selected variant in region 410; a design variant positioned in region 426 may have a greater density than user-selected variant 430 and a greater amount of open space or green space than user-selected variant in region 410; a design variant positioned in region 428 may have a lower density than user-selected variant in region 410 and may generally have the same amount of open space or green space than user-selected variant in region 410; a design variant positioned in region 430 may have a greater density than user-selected variant in region 410 and may generally have the same amount of open space or green space than user-selected variant in region 410; a design variant positioned in region 432 may have a lower density than user-selected variant in region 410 and a lower amount of open space or green space than user-selected variant in region 410; a design variant positioned in region 434 may have a lower density than user-selected variant in region 410 and may generally have the same amount of open space or green space than user-selected variant in region 410; and a design variant positioned in region 436 may have a greater density than user-selected variant in region 410 and a lower amount of open space or green space than user-selected variant in region 410.

It should be noted that the parameters in grid 400 can be selected in any suitable manner. For example, the parameters can be randomly selected from a number of parameters that are used to generate variants or design alternatives (e.g., amount of sunlight or daylight access, amount of open space, amount of gross floor area, etc.). In another example, the parameters can be selected by a user that is using the generative design system (e.g., by receiving an input on parameters that are important to the user).

In some embodiments, the design variant within each region (e.g., regions 422-436) can be highlighted to show particular portions of the design that were mutated or were otherwise changed from the user-selected variant in region 410. For example, in response to selecting the design variant in region 422, an enlarged view of the selected district design can be presented in which the user can manipulate the enlarged view to view different perspectives of the proposed district. In continuing this example, the enlarged view of the district design can present highlighted portions of the design that were mutated or were otherwise changed from the user-selected variant in region 410 (e.g., a portion of the design that was converted to additional green space, a portion of the design that contributes to an increase in density, etc.).

Referring back to FIG. 4, the generative design system can continue to receive user feedback, such as selected design variants, while continuing to generate new variants. In some embodiments, the generative design system can allow the user to change the parameters of interest while continuing to generate additional design variants and while continuing to provide user-selected design variants to seed the generation of new variants.

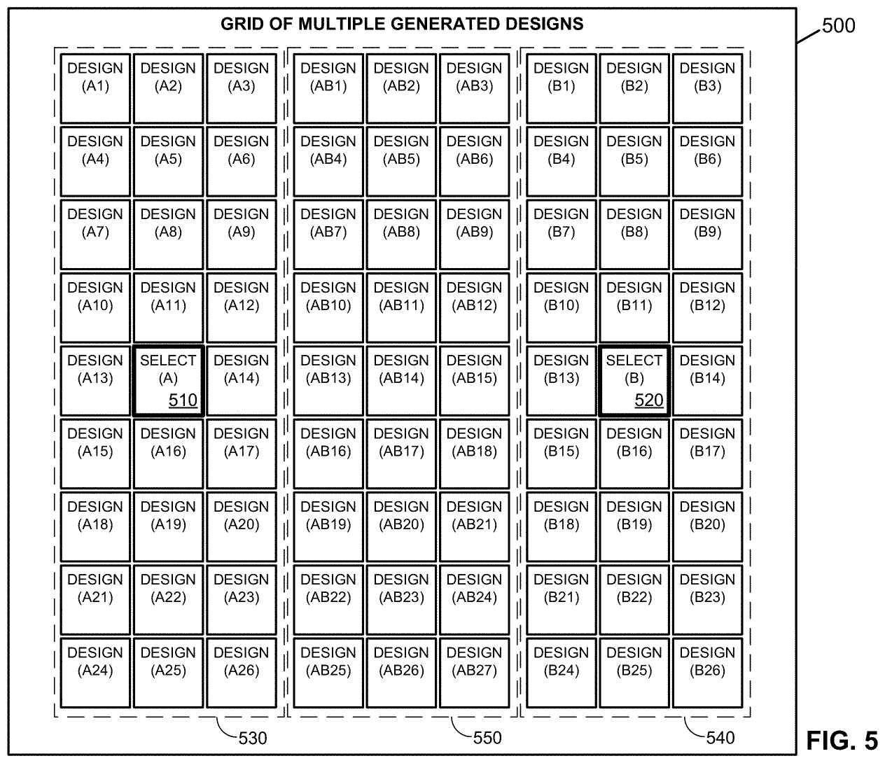

In some embodiments, as noted above, multiple variants can be selected by the user. For example, as shown in FIG. 5, upon indicating that the user prefers to select multiple design variants, in response to selecting multiple design variants from a grid, or in response to selecting a preferred design variant from one grid and selecting a preferred design variant from another grid, the generative design system can expand the grid layout (such as the ones shown in FIGS. 1-4) from a smaller grid layout (a 3×3 grid layout) to a larger grid layout (a 9×9 grid layout).

Generally speaking, in response to selecting multiple design variants (e.g., selected design variant (A) 510 and selected design variant (B) 520), the generative design system can use the genetic algorithm to mutate or otherwise make modifications to design variants 510 and 520 to generate a new batch or set of variants or design alternatives for evaluation by the user. For example, as shown in FIG. 5, the new batch of design variants can include design variants (A1-A26) that mutate selected design variant (A) 510 in grid portion 530, design variants (B1-B26) that mutate selected design variant (B) 520 in grid portion 540, and design variants that mutate some combination of design variant (A) 510 and design variant (B) 520 in grid portion 550. Alternatively, in another example, the new batch of design variants can include design variants that mutate some combination of design variant (A) 510 and design variant (B) 520 in grid portion 550, design variants in grid position 530 in which the mutations are less dependent on design variant (B) 520, and design variants in grid position 540 in which the mutations are less dependent on design variant (A) 510.

Similar to FIG. 4, each grid portion in FIG. 5 can include axes that correspond to particular parameters. For example, the parameters can include an amount of green space on the y-axis and density on the x-axis. In a more particular example, the position of the variant or design alternative within grid 400 can provide the user with an indication as to how the user-selected variant in region 410 was mutated. In another example, each 3×3 grid within grid portions 530, 540, and 550 can correspond to different parameters in which the design variants illustrate the intersection between those different parameters. In continuing this example, the generative design system can select parameters that may be considered important to the user based on the selected design variants (e.g., open space, daylight access, gross floor area, and energy efficiency).

In some embodiments, portions of the generated design variant within each region in the 9×9 grid can be highlighted to show particular portions of the design that were mutated or were otherwise changed from the user-selected variant. For example, in response to selecting multiple design variants, an enlarged view of a selected district design can be presented in which the user can manipulate the enlarged view to view different perspectives of the proposed district. In continuing this example, the enlarged view of the district design can present portions of the design highlighted in one color that were mutated or were otherwise changed from a first user-selected variant (e.g., a portion of the design that was converted to additional green space, a portion of the design that contributes to an increase in density, etc.) and can present portions of the design highlight in another color that were mutated or were otherwise changed from a second user-selected variant. In further continuing this example, the enlarged view of the district design can illustrate portions of the design that were mutated or were otherwise changed based on an intersection of the first user-selected variant and the second user-selected variant.

It should be noted that, in some embodiments, the user can select any suitable design variant and can indicate any suitable reason to associate with the selected design variant. For example, the user of the generative design system can select a preferred design variant and a design variant that is not preferred (e.g., too much open space, not enough daylight access, etc.). In generating design alternatives based on the selected variants, the generative design system can use the genetic algorithm to mutate or otherwise make modifications to the selected design variants to generate a new batch or set of variants or design alternatives for evaluation by the user. For example, as shown in FIG. 5, the new batch of design variants can include design variants (A1-A26) that mutate selected design variant (A) 510 in grid portion 530 in which selected design variant (A) is a preferred design variant, design variants (B1-B26) that mutate selected design variant (B) 520 in grid portion 540 in which selected design variant (B) is a design variant that is not preferred, and design variants that mutate some combination of design variant (A) 510 and design variant (B) 520 in grid portion 550. In reviewing this grid 500 of newly generated design variants, the user of the generative design system can confirm whether a design is not preferred—e.g., by reviewing alternative design variants based on the design variant that is not preferred, by reviewing alternative design variants based on a combination of the design variant that is not preferred and the design variant that is preferred, etc.

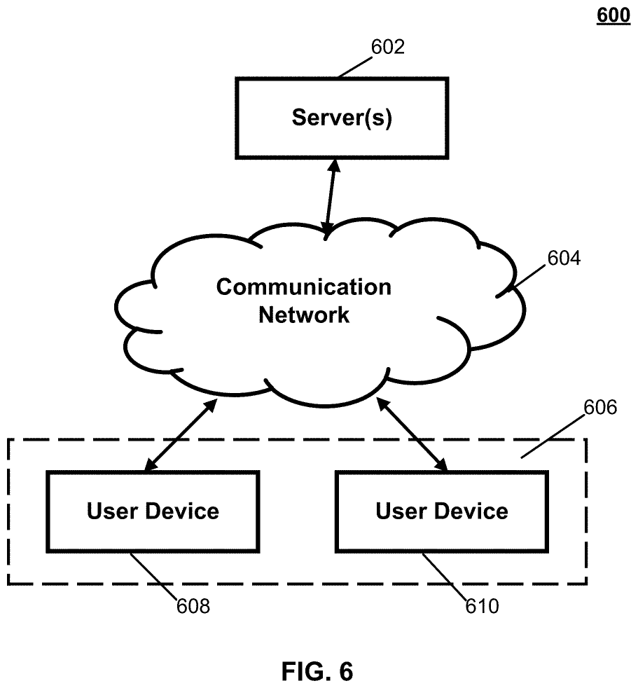

Turning to FIG. 6, an example 600 of hardware for generative urban design with user-guided optimization features that can be used in accordance with some embodiments of the disclosed subject matter is shown. As illustrated, hardware 600 can include a server 602, a communication network 604, and/or one or more user devices 606, such as user devices 608 and 610.

In some embodiments, server 602 can be any suitable server for storing data and/or programs, executing programs (e.g., executing a genetic algorithm in a generative design system to generate multiple variants based on user-selected feedback, as described above in connection with FIGS. 1-5), and/or for any other suitable function(s). For example, in some embodiments, server 602 can store a particular user-selected variant, characteristics of a user-selected variant, and/or any other suitable type of information that can be used for generating new variants. As another example, in some embodiments, server 602 can store a program used for generative urban design with user-guided optimization features, as described above in connection with FIGS. 1-5. Note that, in instances in which server 602 executes a program or an algorithm for generative urban design with user-guided optimization features, server 602 can receive any suitable input parameters or instructions from user device 606. In some embodiments, server 602 can be omitted.

Communication network 604 can be any suitable combination of one or more wired and/or wireless networks in some embodiments. For example, communication network 604 can include any one or more of the Internet, an intranet, a wide-area network (WAN), a local-area network (LAN), a wireless network, a digital subscriber line (DSL) network, a frame relay network, an asynchronous transfer mode (ATM) network, a virtual private network (VPN), and/or any other suitable communication network. User devices 606 can be connected by one or more communications links to communication network 604 that can be linked via one or more communications links to server 602. The communications links can be any communications links suitable for communicating data among user devices 606 and server 602, such as network links, dial-up links, wireless links, hard-wired links, any other suitable communications links, or any suitable combination of such links.

User devices 606 can include any one or more user devices suitable for storing data or programs, executing programs, transmitting input parameters or instructions to server 602, transmitting user-selected variants and corresponding information, presenting user interfaces that provide a user-selected variant along with a grid of newly mutated variants (e.g., as shown in and described above in connection with FIGS. 1-5), and/or for performing any other suitable function(s). For example, in some embodiments, user devices 606 can include a desktop computer, a laptop computer, a mobile phone, a tablet computer, and/or any other suitable type of user device.

Although server 602 is illustrated as one device, the functions performed by server 602 can be performed using any suitable number of devices in some embodiments. For example, in some embodiments, multiple devices can be used to implement the functions performed by server 602.

Although two user devices 608 and 610 are shown in FIG. 6 to avoid over-complicating the figure, any suitable number of user devices, and/or any suitable types of user devices, can be used in some embodiments.

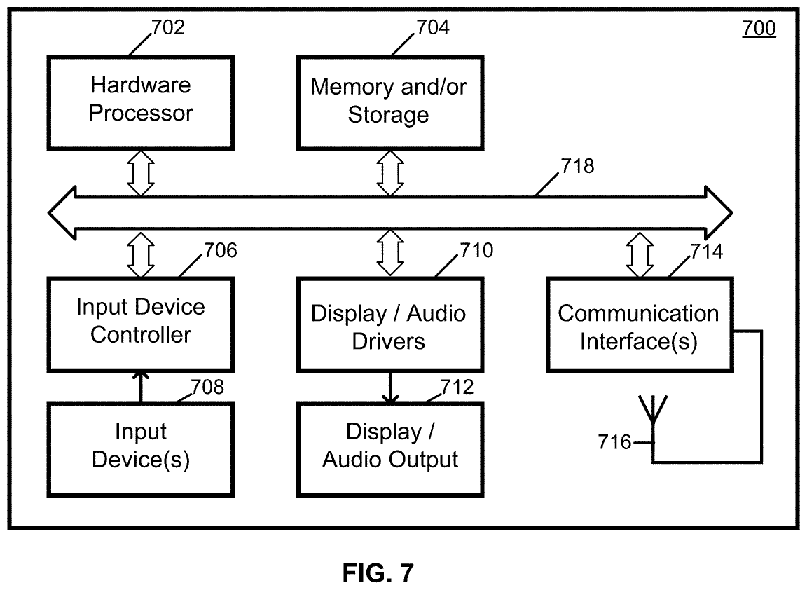

Server 602 and user devices 606 can be implemented using any suitable hardware in some embodiments. For example, in some embodiments, server 602 and user devices 606 can be implemented using any suitable general purpose computer or special purpose computer. For example, a mobile phone may be implemented using a special purpose computer. Any such general purpose computer or special purpose computer can include any suitable hardware. For example, as illustrated in example hardware 700 of FIG. 7, such hardware can include hardware processor 702, memory and/or storage 704, an input device controller 706, an input device 708, display/audio drivers 710, display and audio output circuitry 712, communication interface(s) 714, an antenna 716, and a bus 718.

Hardware processor 702 can include any suitable hardware processor, such as a microprocessor, a micro-controller, digital signal processor(s), dedicated logic, and/or any other suitable circuitry for controlling the functioning of a general purpose computer or a special purpose computer in some embodiments. In some embodiments, hardware processor 702 can be controlled by a server program stored in memory and/or storage of a server, such as server 502. In some embodiments, hardware processor 702 can be controlled by a computer program stored in memory and/or storage 704 of user device 506.

Memory and/or storage 704 can be any suitable memory and/or storage for storing programs, data, and/or any other suitable information in some embodiments. For example, memory and/or storage 704 can include random access memory, read-only memory, flash memory, hard disk storage, optical media, and/or any other suitable memory.

Input device controller 706 can be any suitable circuitry for controlling and receiving input from one or more input devices 708 in some embodiments. For example, input device controller 706 can be circuitry for receiving input from a touchscreen, from a keyboard, from one or more buttons, from a voice recognition circuit, from a microphone, from a camera, from an optical sensor, from an accelerometer, from a temperature sensor, from a near field sensor, from a pressure sensor, from an encoder, and/or any other type of input device.

Display/audio drivers 710 can be any suitable circuitry for controlling and driving output to one or more display/audio output devices 712 in some embodiments. For example, display/audio drivers 710 can be circuitry for driving a touchscreen, a flat-panel display, a cathode ray tube display, a projector, a speaker or speakers, and/or any other suitable display and/or presentation devices.

Communication interface(s) 714 can be any suitable circuitry for interfacing with one or more communication networks (e.g., computer network 504). For example, interface(s) 714 can include network interface card circuitry, wireless communication circuitry, and/or any other suitable type of communication network circuitry.

Antenna 716 can be any suitable one or more antennas for wirelessly communicating with a communication network (e.g., communication network 504) in some embodiments. In some embodiments, antenna 716 can be omitted.

Bus 718 can be any suitable mechanism for communicating between two or more components 702, 704, 706, 710, and 714 in some embodiments.

Any other suitable components can be included in hardware 700 in accordance with some embodiments.

In some embodiments, at least some of the above described blocks of the processes of FIG. 1 can be executed or performed in any order or sequence not limited to the order and sequence shown in and described in connection with the figure. Also, some of the above blocks of FIG. 1 can be executed or performed substantially simultaneously where appropriate or in parallel to reduce latency and processing times. Additionally or alternatively, some of the above described blocks of the process of FIG. 1 can be omitted.

In some embodiments, any suitable computer readable media can be used for storing instructions for performing the functions and/or processes herein. For example, in some embodiments, computer readable media can be transitory or non-transitory. For example, non-transitory computer readable media can include media such as non-transitory forms of magnetic media (such as hard disks, floppy disks, and/or any other suitable magnetic media), non-transitory forms of optical media (such as compact discs, digital video discs, Blu-ray discs, and/or any other suitable optical media), non-transitory forms of semiconductor media (such as flash memory, electrically programmable read-only memory (EPROM), electrically erasable programmable read-only memory (EEPROM), and/or any other suitable semiconductor media), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Accordingly, methods, systems, and media for generative urban design with user-guided optimization features as provided.

Although the invention has been described and illustrated in the foregoing illustrative embodiments, it is understood that the present disclosure has been made only by way of example, and that numerous changes in the details of implementation of the invention can be made without departing from the spirit and scope of the invention. Features of the disclosed embodiments can be combined and rearranged in various ways.

What is claimed is:

1. A method for evaluating design variants of proposed districts, the method comprising:
generating, by a hardware processor, a first plurality of district designs using a genetic algorithm of a generative design system;
causing, by the hardware processor, the first plurality of district designs to be presented in a grid representation for evaluation by a user of a computing device, wherein each region of the grid representation is associated with one of the first plurality of district designs and wherein each region of the grid representation is selectable by the user of the computing device;
receiving, from the user of the computing device, a selected region corresponding to a district design from the first plurality of district designs being presented in the grid representation; and
in response to receiving the selected region, inputting, by the hardware processor, the selected district design as a seed to the genetic algorithm of the generative design system to generate a second plurality of district designs and replacing the first plurality of district designs in the grid representation with the second plurality of district designs for evaluation by the user of the computing device.

2. The method of claim 1, further comprising:
determining a score for each district design in the first plurality of district designs;
selecting a first subset of the first plurality of district designs based on the determined score; and
mutating, using the genetic algorithm of the generative design system, the first subset of the first plurality of district designs to generate a second subset of the first plurality of district designs, wherein the first subset of the first plurality of district designs are presented in the grid representation.

3. The method of claim 2, wherein the score is based on open space percentage, daylight percentage, and total gross floor area of a district design.

4. The method of claim 1, wherein, in response to receiving the selected region corresponding to the district design from the first plurality of district designs being presented in the grid representation, a user interface that includes an enlarged view of the design district is presented, wherein a plurality of views of the design district are available.

5. The method of claim 4, wherein the enlarged view of the design district highlights a portion of the district design that was modified by the genetic algorithm of the generative design system in comparison with the selected district design.

6. The method of claim 1, wherein a plurality of selected regions corresponding to a subset of the district designs is received and wherein, in response to receiving the plurality of selected regions, the subset of district designs is input as seeds to the genetic algorithm of the generative design system to generate the second plurality of district designs and the first plurality of district designs in the grid representation is replaced with the second plurality of district designs for evaluation by the user of the computing device.

7. The method of claim 1, wherein, in response to receiving the selected region corresponding to the district design from the first plurality of district designs being presented in the grid representation, a thumbnail representation of the selected district design is presented in a window region that is adjacent to the grid representation.

8. The method of claim 1, wherein, in response to receiving the selected region corresponding to the district design from the first plurality of district designs being presented in the grid representation, the selected district design is positioned in a central region of the grid representation.

9. The method of claim 8, wherein the grid representation is associated with axes that each correspond to a parameter and wherein each of the second plurality of district designs is positioned within the grid representation based on a parameter value of one of the second plurality of district designs in relation to the parameter value of the selected district design in the central region of the grid representation.

10. The method of claim 8, wherein the parameter associated with each axis is selectable by the user of the computing device.

11. A system for evaluating design variants of proposed districts, the system comprising:
a hardware processor that is configured to:
generate a first plurality of district designs using a genetic algorithm of a generative design system;
cause the first plurality of district designs to be presented in a grid representation for evaluation by a user of a computing device, wherein each region of the grid representation is associated with one of the first plurality of district designs and wherein each region of the grid representation is selectable by the user of the computing device;
receive, from the user of the computing device, a selected region corresponding to a district design from the first plurality of district designs being presented in the grid representation; and
in response to receiving the selected region, input the selected district design as a seed to the genetic algorithm of the generative design system to generate a second plurality of district designs and replacing the first plurality of district designs in the grid representation with the second plurality of district designs for evaluation by the user of the computing device.

12. The system of claim 11, wherein the hardware processor is further configured to:
determine a score for each district design in the first plurality of district designs;
select a first subset of the first plurality of district designs based on the determined score; and
mutate, using the genetic algorithm of the generative design system, the first subset of the first plurality of district designs to generate a second subset of the first plurality of district designs, wherein the first subset of the first plurality of district designs are presented in the grid representation.

13. The system of claim 12, wherein the score is based on open space percentage, daylight percentage, and total gross floor area of a district design.

14. The system of claim 11, wherein, in response to receiving the selected region corresponding to the district design from the first plurality of district designs being presented in the grid representation, a user interface that includes an enlarged view of the design district is presented, wherein a plurality of views of the design district are available.

15. The system of claim 14, wherein the enlarged view of the design district highlights a portion of the district design that was modified by the genetic algorithm of the generative design system in comparison with the selected district design.

16. The system of claim 11, wherein a plurality of selected regions corresponding to a subset of the district designs is received and wherein, in response to receiving the plurality of selected regions, the subset of district designs is input as seeds to the genetic algorithm of the generative design system to generate the second plurality of district designs and the first plurality of district designs in the grid representation is replaced with the second plurality of district designs for evaluation by the user of the computing device.

17. The system of claim 11, wherein, in response to receiving the selected region corresponding to the district design from the first plurality of district designs being presented in the grid representation, a thumbnail representation of the selected district design is presented in a window region that is adjacent to the grid representation.

18. The system of claim 11, wherein, in response to receiving the selected region corresponding to the district design from the first plurality of district designs being presented in the grid representation, the selected district design is positioned in a central region of the grid representation.

19. The system of claim 18, wherein the grid representation is associated with axes that each correspond to a parameter and wherein each of the second plurality of district designs is positioned within the grid representation based on a parameter value of one of the second plurality of district designs in relation to the parameter value of the selected district design in the central region of the grid representation.

20. The system of claim 18, wherein the parameter associated with each axis is selectable by the user of the computing device.

21. A non-transitory computer-readable medium containing computer executable instructions that, when executed by a processor, cause the processor to perform a method for evaluating design variants of proposed districts, the method comprising:
generating a first plurality of district designs using a genetic algorithm of a generative design system;
causing the first plurality of district designs to be presented in a grid representation for evaluation by a user of a computing device, wherein each region of the grid representation is associated with one of the first plurality of district designs and wherein each region of the grid representation is selectable by the user of the computing device;
receiving, from the user of the computing device, a selected region corresponding to a district design from the first plurality of district designs being presented in the grid representation; and
in response to receiving the selected region, inputting the selected district design as a seed to the genetic algorithm of the generative design system to generate a second plurality of district designs and replacing the first plurality of district designs in the grid representation with the second plurality of district designs for evaluation by the user of the computing device.
